(19) United States
(12) Patent Application Publication
(10) Pub. No.: US 2023/0073405 A1
(43) Pub. Date: Mar. 9, 2023

(54) METHOD FOR PRODUCING A SEMICONDUCTOR ASSEMBLY AND DIODE LASER

(71) Applicant: JENOPTIK Optical Systems GmbH, Jena (DE)

(72) Inventor: Matthias SCHROEDER, Weimar (DE)

(73) Assignee: JENOPTIK Optical Systems GmbH, Jena (DE)

(21) Appl. No.: 17/642,981

(22) PCT Filed: Sep. 15, 2020
(86) PCT No.: PCT/EP2020/075720

§ 371 Date: Nov. 10, 2022

(30) Foreign Application Priority Data
Sep. 16, 2019 (DE) 10 2019 124 822.1
Sep. 17, 2019 (DE) 10 2019 124 993.7

(51) Int. Cl. H01S 5/024; H01S 5/042; H01S 5/02365; H01S 5/02315; H01S 5/40

(52) U.S. Cl. CPC H01S 5/02476; H01S 5/04252; H01S 5/02365; H01S 5/02315; H01S 5/4031

(57) ABSTRACT

The invention relates to a method for producing a semiconductor assembly, in particular connecting a semiconductor chip to a heat sink. A first metal layer consisting of Pb, Cd, In or Sn is made so thin that it is bonded by means of an opposing second metal layer consisting of another metal, for example gold, in a layer consisting of intermetallic phases. This can prevent migration of the soft metals. The brittle intermetallic layer is prevented from fracturing by a continuous pressing force.

This nonprovisional application is a National Stage of International Application No. PCT/EP2020/075720, which was filed on Sep. 15, 2020, and which claims priority to German Patent Application No. 10 2019 124 822.1, which was filed in Germany on Sep. 16, 2019, and German Patent Application No. 10 2019 124 993.7, which was filed in Germany on Sep. 17, 2019, and which are all herein incorporated by reference.

### BACKGROUND OF THE INVENTION

### Field of the Invention

The invention relates to a method for producing a semiconductor assembly, more particularly a diode laser, and to a diode laser. The diode laser comprises a laser bar which is disposed between a heat-conducting body and a cover. The heat-conducting body and the cover serve as electrical contacts through which the operating current is passed to the laser bar.

### Description of the Background Art

For a long time there have been methods known for producing a diode laser by soldering a laser bar to a heat sink on the p side and contacting it on the n side via bond wires—from U.S. Pat. No. 5,105,429A and U.S. Pat. No. 4,716,568A, for example. A disadvantage is the limited current-carrying capacity of the bond wires.

A current-carrying capacity of the n-side current connection can be increased through the use of a solid lid which may take the form of a second heat-conducting body. WO2009143835 and WO2009146683 disclose the soldering of the laser bar between two heat-conducting bodies. The soldering operation may lead to tensions in the laser bar that may adversely affect the electrooptical properties. WO2011029846 discloses a method for producing a diode laser without involving a soldering operation, in which a first metallic layer is used between the first contact face of the laser bar and the first heat-conducting body, and a second metallic layer is used between the second contact face of the laser bar and the second heat-conducting body. These layers, which may consist of indium, for example, produce a material bond on assembly.

WO2016135160A1 discloses a method for securing a laser bar at low temperature between a heat-conducting body and a cover.

All soldering and other connecting processes use an indium layer which is several μm thick and which after assembly is present in the completed semiconductor device. This is considered advantageous so that the indium layer is able, by plastic deformation, to compensate the difference in thermal expansion between heat sink and semiconductor chip, in order to avoid thermal stresses. A sufficient thickness of the indium layer has to date been considered necessary, since intermetallic mixed phases such as AuIn₂, for example, which may be formed during soldering or as a result of diffusion, are comparatively hard and brittle. A disadvantage is that particularly in the case of pulsed operation of a conventional diode laser, there may be migration of material from the indium layers. As a result the laser may fail. In order to avoid indium layers, the use of expansion-adaptive heat sink materials is recommended.

### SUMMARY OF THE INVENTION

It is an object of the invention to specify a method for producing a diode laser which exhibits an improved lifetime in pulsed operation.

It has emerged that, surprisingly, intermetallic mixed phases such as AuPb₂, AuCd₃, AuIn₂, AuIn, AuSn₄, AuSn₂ and AuSn are entirely suitable for producing a durable connection between a semiconductor chip and a heat-conducting body. It has emerged, indeed, that it may be favorable to bind the soft metals In or Sn that are typically used for joining as far as possible into hard intermetallic mixed phases with gold (Au).

The object is achieved by a method for producing a semiconductor assembly, characterized by the following steps:
a. providing at least one semiconductor chip having on a first side a first contact face and having on a second side, opposite the first side, a second contact face,
b. providing a heat-conducting body having a first connection face,
c. providing a cover having a second connection face,
d. producing a first metallic layer comprising one or more of the soft metals lead, cadmium, indium, tin,
e. producing a second metal layer, where either the first metallic layer is produced on the first connection face and the second metal layer is produced on the first contact face, or vice versa,
f. disposing the semiconductor chip between the heat-conducting body and the cover, where the first contact face is facing the first connection face of the heat-conducting body and the second contact face is facing the second connection face of the cover,
g. generating at least one force which has a component which presses the cover in the direction of the heat-conducting body, where under the action of the force the first metallic layer is pressed areally onto the second metal layer,
h. establishing a mechanical connection of the cover to the heat-conducting body that at least partly maintains the force,
i. forming an intermetallic layer by solid-state diffusion of the first metallic layer into the second metal layer and/or vice versa, where the first metallic layer is bound predominantly in intermetallic mixed phases and/or oxidically.

With this method it is possible to produce a diode laser as in claim 12 that achieves the object of the invention. For producing a clamped connection it is possible advantageously in the method identified above to use a second metallic layer in the form of a nubbed structure in accordance with claim 15.

The method of the invention may be used advantageously to produce a diode laser which is designed for a high operating current and/or for pulsed operation.

The semiconductor assembly of the invention may be a diode laser, more particularly a device for the emission of laser radiation, which has a laser bar as beam source. The semiconductor chip may therefore take the form of a laser bar. The semiconductor chip may alternatively take the form, for example, of a MOSFET, IGBT, thyristor, rectifier diode or the like. The laser bar may take the form, conventionally of an edge-emitting diode laser bar and may comprise one or, preferably, two or more emitters, which may be disposed relatively to one another with an offset in each case in an x-direction. The laser bar may preferably have a width between 0.3 mm and 12 mm in x-direction. It may preferably have 1 to 49 emitters. The thickness of the laser bar may be preferably between 0.05 mm and 0.2 mm in a y-direction. The length of the emitters of the laser bar in a z-direction may be preferably between 0.5 mm and 6 mm. The direction of the central beams of the emitted laser radiation may be the z-direction. The directions x, y and z may be at right angles to one another. The laser bar may have a known epitaxially produced layer sequence as p-n junction with one or more quantum trenches. The epitaxial layer may be considerably thinner than the substrate. The epitaxial layer may be for example between 3 μm and 20 μm thick. The substrate may be for example between 50 μm and 200 μm thick. The individual emitters may take the form preferably of broad-strip emitters or of ridge waveguides or of trapezoidal lasers. There may also be multiple layer sequences, i.e., multiple p-n junctions lying electrically in series. Such bars are also referred to as a nanostack. In this case there may be multiple emitters stacked one atop another in the y-direction.

The facets of the laser bar may be provided with mirrors; for example, on the rear facet of the laser element there may be a highly reflective mirror layer mounted, and on the opposite exit-side facet, which contains the exit aperture, there may be a low-reflective mirror layer having a reflectivity of 0.1% to 10%, for example. The mirrors may define a laser resonator, which enables laser operation. The laser bar may alternatively take the form of a gain element, which is intended for laser operation only in interaction with an external resonator. In this case, for example, a wavelength-dependent feedback may be provided through the external resonator that serves to set the wavelength of the laser. An electrooptical gain element of this kind is also understood as a laser bar in the sense of the invention.

The laser bar may be pumped by an electric current. The operating current may be 1 A to 1000 A, for example. For current input, a first contact face and a second contact face are provided on the laser bar. The p-side contact face may be referred to as the first contact face. The first contact face may be the anode of the diode laser bar. The n-side contact face of the laser bar may be referred to as the second contact face. The second contact face may be the cathode of the laser bar. The first and second contact faces may each lie in an xz-plane. The first contact face may be disposed on the epitaxial side of the laser bar, which may be referred to as the first side, while the second contact face may be disposed on the substrate side of the laser bar, which may be referred to as the second side. Metallization may feature on the first and/or second contact faces.

The laser bar in operation may evolve waste heat, which must be removed. A heat-conducting body having a first connection area is provided for this purpose. Since the pn junction of the diode laser may be located in the epitaxial layer (i.e., near the first side) and since the predominant proportion of the waste heat may arise in the pn junction, the heat-conducting body may be connected preferably to the first side of the laser bar. The first contact face may be connected electrically and thermally to the first connection face and the second contact face may be connected electrically to the second connection face.

The method of the invention serves for producing a semiconductor assembly. Provided for this purpose is a semiconductor chip, a laser bar for example, which on a first side has a first contact face and on a second side, opposite the first side, has a second contact face. The first contact face may take the form of a contact face for all the emitters. It may alternatively consist of multiple individual subfaces, which may be separate from one another—for example, one subface for each emitter. The first contact face may be, for example, a metallization, and the outer layer may be, for example, a gold layer. In that case it is preferable to use a galvanically reinforced gold layer having a thickness preferably of greater than 0.5 μm, more preferably between 1 μm and 10 μm. This galvanically produced gold layer may be the external layer. In the event of this galvanically produced gold layer being the external layer, this layer is to be referred to as second metal layer. Alternatively, on this galvanically produced metal layer, there may be a diffusion barrier layer disposed, which is referred to below, for differentiation, as second diffusion barrier layer. This layer may comprise Ti, Ni, Cr, Pt, Mo and/or W, for example. Disposed externally on the second diffusion barrier layer may be a further metal layer, advantageously of gold, which may for example be at least 80 nm thick, advantageously at least 120 nm thick, more advantageously at least 200 nm thick. In this case this external metal layer—more particularly gold layer—is referred to below as second metal layer. In this case the galvanic gold layer optionally present and disposed under the second diffusion barrier layer, referred to below as thick-gold sublayer, may be irrelevant for the formulation of the intermetallic phases in accordance with the invention.

The second contact face may take the form of a contact face for all the emitters of a laser bar or, in the case of a general semiconductor chip, of a large contact face for current input. It may alternatively consist of multiple individual subfaces—for example, one subface for each emitter of a laser bar, or current contact for different elements of a semiconductor chip. The second contact face may be, for example, a metallization, and the outer layer may be a gold layer, for example. It may be 50 nm to 200 nm thick, for example.

It is also possible to provide multiple laser bars, which may be disposed, for example, next to one another or atop another on the heat sink.

Also provided is a heat-conducting body having a first connection face. The heat-conducting body may for example consist at least partly of copper, aluminum or of a copper-diamond, aluminum-diamond or silver-diamond composite material, or may comprise such a material. It may be made for example as a copper body with an inlay of a composite material. It may alternatively, for example, be fabricated entirely of copper. The heat-conducting body may have a metallization, for example Ag/Au, or Ni/Au or Ti/Pt/Au, in which case the gold layer (Au) is provided preferably on the outside. The Ag, Ni, Ti or Pt layer disposed beneath it may be provided as a first diffusion barrier layer, by preventing diffusion of atoms of the first metallic layer. The first connection face may be made with a particularly good planarity, in order thereafter to achieve a low smile value (deviation of the individual emitters from a straight line). It is also possible for further first connection faces to be provided for further laser bars.

Also provided is at least one cover with a second connection face. The cover may be intended for the electrical contacting of the n-type contact of the laser bar. It may but need not be likewise intended for the diversion of heat. It may consist of a material having good electrical conductivity, as for example at least partly of copper, aluminum or of a copper-diamond, aluminum-diamond or silver-diamond composite material, or may comprise such a material. It may be made, for example, as a copper body with an inlay of a composite material. It may alternatively, for example, be fabricated entirely of copper. The cover may have a metallization, for example Ag/Au, or Ni/Au or Ti/Pt/Au, in which case the gold layer is provided preferably on the outside.

In accordance with the invention a first metallic layer is provided. The first metallic layer may consist of a soft metal, which preferably has a yield point under compressive loading (compressive yield point) of less than 50 MPa, more preferably less than 20 MPa or very preferably less than 10 MPa. The first metallic layer comprises one or more of the soft metals lead, cadmium, indium and tin. It may advantageously consist of pure lead, pure indium or pure tin. A layer of this kind may be produced, for example, by a coating operation such as vapor deposition or sputtering. This layer may be considerably thinner by comparison with existing connection technologies as set out below. This layer may take the form of a uniform layer. Alternatively it may be structured, with a nubbed structure, for example. The use of indium and/or tin is preferred, since lead and cadmium are less eco-friendly.

In accordance with the invention a second metallic layer made of a different metal from the first metal layer is provided, advantageously of gold. This layer is also referred to below as second metal layer. It may contain impurities or doping, but may advantageously consist substantially of gold—it may comprise, for example, more 95%, better still more than 99% of the amount of substance, of gold. This layer may be produced by coating, such as vapor deposition, sputtering, or galvanically.

The first metallic layer may be produced on the first connection face, and the second metal layer on the first contact face. An alternative possibility is to produce the first metallic layer on the first contact face, and the second metal layer on the first connection face.

In accordance with the invention the laser bar is disposed between the heat-conducting body and the cover, where the first contact face is facing the first connection face of the first heat-conducting body, and the second contact face is facing the second connection face of the cover, and the second metallic layer is disposed at least in sections between the second connection face and the second contact face.

In accordance with the invention at least one force is generated having a component which presses the cover in the direction of the heat-conducting body. This may be the direction y. Under the effect of the force, the first contact face is pressed areally onto the first connection face. This may lead to a clamped connection. Under this applied pressure, unevenness's can be compensated. The laser bar may be elastically deformed in this case. Under the effect of the force, the first metallic layer is pressed areally onto the second metal layer.

Provision is also made for the establishment of a mechanical connection of the cover to the heat-conducting body. It is possible advantageously to provide an electrically insulating connection, so that the laser bar is not short circuited. The connection may take place by means of a joining agent. The joining agent used may be an adhesive, for example. With particular advantage a sheetlike bond with a heat-conducting adhesive may be used. Between the laser bar and the joining face there may be a distance or a parting trench provided in order to prevent the laser bar being wetted with adhesive. The establishment of the mechanical connection may entail a volume contraction of the joining agent. The mechanical connection may be intended to generate and/or to maintain the force. In that case it may be sufficient if the force is maintained at least partly. A partial relaxation of the force after the connecting operation may be intended or tolerable. The force or the maintained fraction of the force allows the clamped connection of the laser bar between the heat-conducting body and the cover to be maintained. As a result it is possible to prevent fracture of the intermetallic layer described below. Alternatively or additionally a screw connection may be envisaged for connecting the cover to the heat-conducting body.

The invention provides for the formation of an intermetallic layer by solid-state diffusion of the first metallic layer into the second metal layer and/or vice versa. Solid-state diffusion may be understood as that the diffusion process takes place without melting. The diffusing may take place without heating, at room temperature. Alternatively a heating may be envisaged, and so the diffusion may occur at an elevated temperature. The temperature may advantageously be below the lowest solidus temperatures of the first metallic layer and mixed phases thereof with the second metal layer. This may prevent melting of the first metallic layer and of the mixed phases. As a result it is possible to prevent mechanical stresses.

The invention provides for the method to be implemented such that the first metallic layer is bound into intermetallic mixed phases with the metal of the second metallic layer, preferably gold, and/or oxidically. It may be advantageous to bind the present amount of substance of metal atoms of the first metallic layer predominantly, i.e., to an extent of more than 50%, very advantageously more than 75% and very advantageously completely, apart from insignificant residual amounts. The binding of just 50% of the soft metal atoms may be sufficient, if the intermetallic layer is interdispersed over the entire layer thickness with intermetallic mixed phases. Residual regions between them, with pure layer material of the first metallic layer, may then likewise be hindered from migrating, and so their presence does not detract from the positive effect of the invention. In the case of less than 50% bound metal atoms of the first metallic layer, conversely, the effect may be absent or may be adversely affected. The degree of binding stated above may be achieved by making the first metallic layer sufficiently thin. The layer thickness of the first metallic layer may be less than 2 μm, advantageously less than 1.6 μm, likewise advantageously less than 1.2 μm and likewise advantageously less than 800 nm. It may be at least 200 nm, advantageously at least 500 nm. The reason for the lower limit may be that, in the case of an even thinner first metal layer, it would no longer be possible to compensate unevenness's of the first contact face and/or of the first connection face.

The solid-state diffusion process produces an intermetallic layer. In this way it can be ensured that the connection of the first contact face to the first connection face, which may also be referred to functionally as connecting face, is free from plastically deformable pure metals Pb, Cd, In and Sn. The yield point under compressive loading (compressive yield point) and/or the yield point under shearing load of the intermetallic layer may be at least twice, advantageously five times, that of the first metallic layer.

In the case of conventional connecting processes with an indium layer according to the extinct state of the art, conversely, the yield point is barely increased, since after assembly there is still a layer of pure indium present.

The first, second and third metallic layers may be produced by coating. Coating is understood in production engineering to refer to a main group of the fabrication processes according to DIN 8580 that are utilized for applying an adhering layer of formless substance to the surface of a workpiece. The corresponding operation and the applied layer itself are also referred to as coating. A coating may be a thin layer or a thick layer and may also comprise multiple inherently coherent layers; the distinction is not precisely defined and is guided by the coating method and intended application. In the sense of the present invention, a coating with a location-dependent layer thickness may also be referred to as a layer.

The first metallic layer may be produced by coating of the first connection face. This may be done using galvanic or physical (e.g., vapor deposition, sputtering) coating methods. Coating may take place with a mask, to produce a structured layer. Alternatively, a uniformly thick layer may also be coated. The second metallic layer may be produced advantageously by coating of the second contact face of the laser bar with gold.

Advantageously the cover may be provided so as to contribute to the diversion of heat from the second contact face. The hollows in any third metallic layer present, i.e., the areas between the nubs, may remain free or may alternatively be filled in with a further joining agent, such as an epoxy resin. The filling of the hollow areas may take place in a further method step. It may optionally be possible in this way to improve the mechanical strength of the connection relative to a connection with unfilled cavities. The cover may be connected thermally and mechanically to the heat-conducting body by means of an electrically insulating joining agent.

Partial oxidation of the first metallic layer before step f) may be advantageous. This may be accomplished by dipping the coated face using hydrogen peroxide solution, using water, and/or by storage in an oxygen-containing atmosphere. In this way a part of the amount of substance of the metals of the first metallic layer may be bound oxidically. This allows the required layer thickness of the second metal layer to be reduced. If sufficient gold is available, there may be no need for oxidizing.

A fourth metal layer, a layer of gold for example, may be disposed under the first metallic layer. A gilded heat-conducting body, for example, may be used for this purpose. The heat-conducting body may have, for example, a customary Ni/Au coating. The nickel layer may be 1 μm to 10 μm thick, for example, the external fourth gold layer 50 nm to 200 nm or 50 nm to 500 nm. On the fourth metal layer the first metallic layer may be produced in the region of the first connecting face.

Advantageously the first metallic layer per unit area may contain less than four times the amount of substance of at least one metal able to form mixed phases with the first metal layer, preferably gold, contained in total in the second metal layer and the fourth metal layer. More particularly the first metallic layer may per unit area contain a lower amount of substance of the soft metals lead, cadmium, indium and tin than four times the amount of substance of gold contained per unit area in total in the second metal layer and in the fourth metal layer, where present. From this it is possible to calculate the required maximum layer thickness of the first metallic layer. Alternatively, in the case of a mandated layer thickness of the first metallic layer, it is possible to calculate the required minimum layer thickness of the second metal layer, taking account where appropriate of the fourth metal layer.

A second and/or first diffusion barrier layer may be disposed under the second metal layer and/or under the fourth metal layer. The metals of the first metallic layer may be bound in step i) partly to the metals of the second and/or first diffusion barrier layer. For example, the second and/or first diffusion barrier layer may consist of nickel or chromium or may comprise nickel and/or chromium. In that case a fraction of metal atoms of the first layer may be bound, for example, as indium-nickel, indium-chromium, tin-nickel or tin-chromium mixed phases.

The method may advantageously also be production of a third metallic layer, particularly advantageously with a nubbed structure, on the second connection face and/or on the second contact face. This layer may be produced advantageously of Pb, In and/or Sn. The third metallic layer may advantageously be between 0.5 μm and 5 μm thick.

Advantageous in accordance with the invention is a diode laser comprising at least one edge-emitting laser bar which comprises one or more emitters, having a first contact face, which takes the form of a p-type contact, and a second contact face, which takes the form of an n-type contact, a heat-conducting body having a first connection face, a cover having a second connection face, where the laser bar is disposed between the heat-conducting body and the cover, where the cover is connected mechanically to the heat-conducting body, and the first contact face is areally connected thermally and electrically to the first connection face via an intermetallic layer, and the second contact face is connected electrically to the second connection face, where the intermetallic layer comprises gold (Au) and at least one further metal (ME) from the group lead, cadmium, indium and tin, and the intermetallic layer consists predominantly of one or more mixed phases AuME₃, AuME₂ and/or phases with higher gold fraction. Predominantly may mean more than 50% based on the amount of substance, which can be indicated in moles.

Examples of possible such mixed phases include AuPb₂, AuCd₃, AuIn₂, AuIn, AuSn₄, AuSn₂ and AuSn. The intermetallic layer may advantageously contain predominantly mixed phases which include at most 50% of gold atoms. With particular advantage the intermetallic layer may contain predominantly the mixed phases each with the lowest gold content—for example, AuPb₂, AuCd₃, AuIn₂ and/or AuSn₄. It may be advantageous to produce the first metallic layer of Sn. The mixed phase AuSn₄ is able, for the same amount of substance of gold in comparison to the mixed phases of the other metals, to bind particularly large number of atoms of the first metallic layer.

The cover may advantageously be provided so as to make a contribution to the diversion of heat from the second contact face. The cover may advantageously be connected thermally and mechanically to the heat-conducting body by means of an electrically insulating joining agent.

The intermetallic layer of the invention may be brittle or have a tendency to rupture. This can be avoided by means of a clamping force acting normal to the layer. The use of a permanent clamping force may therefore be advantageous for maintaining a securement of a semiconductor element on a heat-conducting body by means of an intermetallic layer, where the intermetallic layer comprises gold (Au) and at least one further metal (ME) from the group lead, cadmium, indium and tin, and the intermetallic layer consists predominantly of one or more mixed phases AuME₃, AuME₂ and/or phases with higher gold fraction.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a first exemplary embodiment before assembly.

FIG. 2 shows the first exemplary embodiment after assembly.

FIG. 3 shows for comparison a diode laser according to the prior art.

FIG. 4 shows a second exemplary embodiment before assembly.

FIG. 5 shows the third exemplary embodiment after assembly.

FIG. 6 shows a fourth exemplary embodiment.

It should be pointed out that the figures are not drawn to scale. Exaggerated representations, particularly in relation to the respective layer thicknesses, are necessary in order to illustrate the invention.

### DETAILED DESCRIPTION

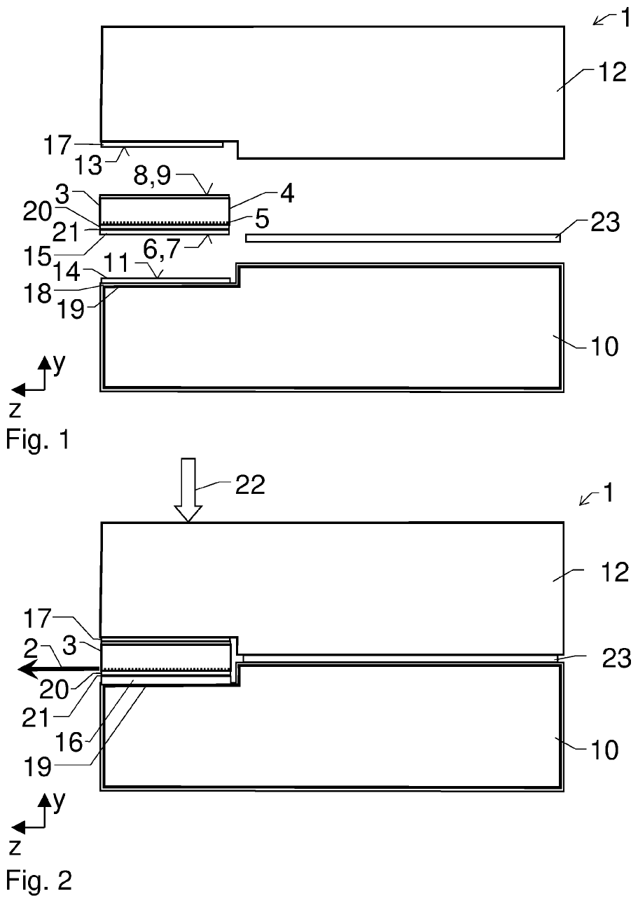

The invention is to be illustrated on the basis of a first exemplary embodiment in FIG. 1 and FIG. 2. FIG. 1 shows a first exemplary embodiment before the assembly of the diode laser 1. The figure represents a provided laser bar 3 with multiple emitters, which on a first side 6 has a first contact face 7, formed as a p-type contact (anode), and on a second side 8, opposite the first side, has a second contact face 9, which takes the form of an n-type contact (cathode). Likewise indicated is the position of the epitaxial layer 5 near to the first contact face of the laser bar, by means of a dotted line. The n-type contact contacts the substrate 4 of the laser bar.

The first contact face bears a coating comprising a thick-gold sublayer 20, covered by a second diffusion barrier layer 21 (represented as a thick line). An external second metal layer of gold 15 is disposed on the second diffusion barrier layer 21.

Additionally represented is a provided heat-conducting body 10 with a first connection face 11. The heat-conducting body 10 is provided with an Ni/Au coating which has an Ni sublayer as first diffusion barrier layer 19 and an external fourth metal layer of gold 18. The first connection face is coated with a first metallic layer 14 of lead, indium or tin. Additionally represented is a provided cover 12 with a second connection face 13. The second connection face carries an applied third metallic layer 17 of indium or tin. In an alternative embodiment this layer has a nubbed structure (not represented). The third metallic layer may therefore be provided together with the cover. The laser bar is disposed between the heat-conducting body 10 and the cover 12, with the first contact face 7 facing the first connection face 11 of the heat-conducting body and the second contact face 9 facing the second connection face 13 of the cover. The cover may have an Ni/Au coating (not represented), in the same way as the heat-conducting body.

Likewise represented is a curable joining agent 23 which may be applied, for example, in the form of an as yet uncured viscous epoxy resin adhesive to the corresponding face of the heat-conducting body or of the cover.

FIG. 2 shows the diode laser 1 during/after assembly. At least one force 22 is generated which has a component that presses the cover 12 in the direction of the heat-conducting body 10. Under the action of the force, the first contact face 7 is pressed areally onto the first connection face 11, and the first metallic layer 14 is pressed areally onto the second metal layer of gold 15.

A mechanical connection is established between the cover 12 and the heat-conducting body 10 by means of the electrically insulating joining agent 23. The cured joining agent at least partly maintains the force 22. The completed diode laser emits laser radiation 2 in direction z.

In the method, an intermetallic layer 16 is formed by solid-state diffusion of the first metallic layer 14 into the second metal layer of gold 15 and/or vice versa, with the first metallic layer 14 being bound into intermetallic mixed phases. An oxidic binding of some of the atoms of the first metallic layer may optionally be present additionally. The second diffusion barrier layer 21 prevents atoms of the first metallic layer penetrating into the thick-gold sublayer 20. As a result the latter layer remains intact. The intermetallic layer 16 is generated between the first diffusion barrier layer 19 and the second diffusion barrier layer 21.

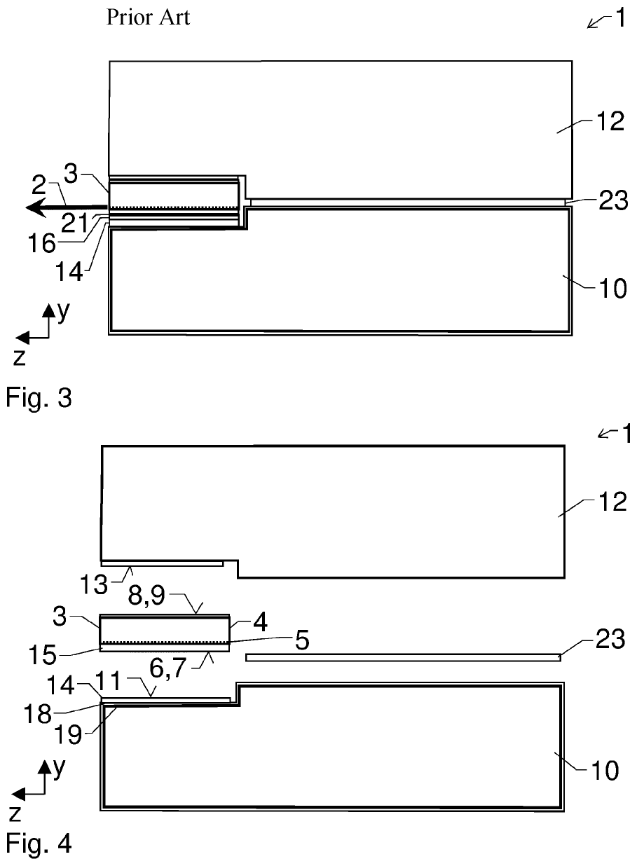

FIG. 3 shows for comparison a diode laser according to the prior art. The diode laser is mounted with an indium layer 14 as first metallic layer. The indium layer is made with a thickness such that it is permanently retained as a layer of pure metal. Only in a zone near to the interface is it possible for intermetallic phases 16 to form, which according to the existing teaching are undesirable.

FIG. 4 shows a second exemplary embodiment before the assembly of the diode laser 1. Here the second metal layer of gold 15 takes the form of a thick-gold layer. A second diffusion barrier layer covering the thick-gold layer is absent in this embodiment.

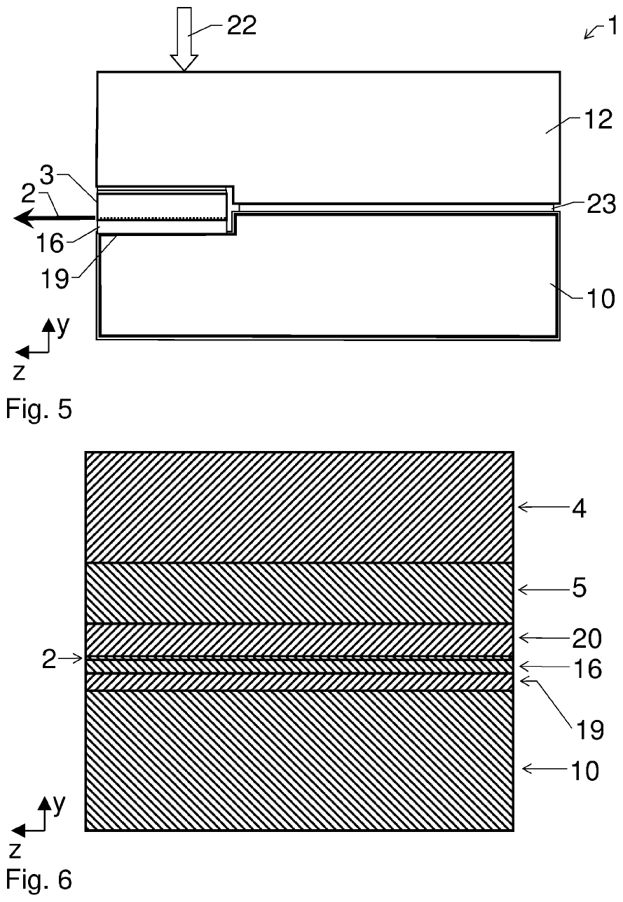

FIG. 5 shows the third exemplary embodiment after assembly. The thick-gold layer mounted on the semiconductor chip is utilized here as a reservoir of gold for forming the intermetallic layer 16. The fourth metal layer of gold also contributes to the reservoir.

Error! Reference source not found. It represents the schematic drawing after an electron micrograph of a polished section of a completed semiconductor assembly, here a diode laser, in an enlarged detail representation. The laser bar has a substrate 4 and an epitaxial layer 5. The first contact face of the laser bar bears a coating comprising a metallic sublayer 20 (buffer layer), about 1 μm to 5 μm thick, which is covered by a second diffusion barrier 21 less than 0.5 μm thick. In the figure, the diffusion barrier layer 21 is visible between the metallic sublayer 20 and the intermetallic layer 16. The metallic sublayer may consist, for example, predominantly of gold, of copper or of tin. Because of the second diffusion barrier layer 21, the metallic sublayer 20 is retained even after the formation of the intermetallic layer 16 in step i) of the method. Before the establishment of the mechanical connection, a second metal layer, preferably of gold, is applied (not visible in the figure) on the second diffusion barrier layer 21. This second metal layer is absorbed completely in the intermetallic layer 16 when the intermetallic layer 16 is formed in step i).

The heat-conducting body 10 is provided with a metallic coating. This coating comprises a first diffusion barrier layer 19, around 0.5 μm to 10 μm thick, which may also be referred to as a buffer layer. Before the establishment of the mechanical connection, a fourth metal layer, preferably of gold, is applied (not visible in the figure) on the first diffusion barrier layer 19. This fourth metal layer is absorbed completely in the intermetallic layer 16 when the intermetallic layer 16 is formed in step i).

Before the establishment of the mechanical connection, the first metallic layer with a thickness of around 0.5 μm to 2 μm (not visible in the figure) is applied to the second metal layer and/or to the fourth metal layer. This first metallic layer is absorbed completely in the intermetallic layer 16 when the intermetallic layer 16 is formed in step i).

The intermetallic layer has a thickness of around 0.5 μm to 2.5 μm. The intermetallic layer 16 comprises mixed phases of the metals of the first, second and fourth metallic layers and optionally oxides of the material of the first metallic layer. The intermetallic layer is free from pure metallic phase of the material of the first metallic layer. It preferably comprises predominantly the respectively least gold-rich intermetallic phase of the metal of the first metallic layer with gold. In one modification of the first exemplary embodiment, the intermetallic layer comprises intermetallic phases of up to 50% gold fraction, measured as the amount of substance, which can be expressed in moles.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for producing a semiconductor assembly, characterized by the following steps:
a. providing at least one semiconductor chip having on a first side a first contact face and having on a second side, opposite the first side, a second contact face,
b. providing a heat-conducting body having a first connection face,
c. providing a cover having a second connection face,
d. producing a first metallic layer comprising one or more of the soft metals lead, cadmium, indium, tin,
e. producing a second metal layer, where either the first metallic layer is produced on the first connection face and the second metal layer is produced on the first contact face, or vice versa,
f. disposing the semiconductor chip between the heat-conducting body and the cover, where the first contact face is facing the first connection face of the heat-conducting body and the second contact face is facing the second connection face of the cover,
g. generating at least one force which has a component which presses the cover in the direction of the heat-conducting body, where under the action of the force the first metallic layer is pressed areally onto the second metal layer,
h. establishing a mechanical connection of the cover to the heat-conducting body (10) that at least partly maintains the force,
i. forming an intermetallic layer by solid-state diffusion of the first metallic layer into the second metal layer and/or vice versa, where the first metallic layer is bound predominantly in intermetallic mixed phases and/or oxidically.

2. The method as claimed in claim 1, further comprising partly oxidizing the first metallic layer before step f).

3. The method as claimed in claim 1, wherein the first metallic layer has a layer thickness of less than 2 μm but at least 200 nm.

4. The method as claimed in claim 1, wherein when the intermetallic layer is formed by solid-state diffusion of the first metallic layer into the second metal layer and/or vice versa, the first metallic layer is bound completely in intermetallic mixed phases and/or oxidically.

5. The method as claimed in claim 1, wherein the yield point of the intermetallic layer under shearing load is at least five times that of the first metallic layer .

6. The method as claimed in claim 1, wherein a fourth metal layer is disposed under the first metallic layer.

7. The method as claimed in claim 1, wherein the first metallic layer per unit area contains a lower amount of substance of the soft metals lead, cadmium, indium and tin than four times the amount of substance of gold contained in total per unit area in the second metal layer and the fourth metal layer.

8. The method as claimed in claim 1, wherein a diffusion barrier layer is disposed under the second metal layer and/or under the fourth metal layer and the metals of the first layer in step i) are bound partly to the metals of the diffusion barrier layer.

9. The method as claimed in claim 1, wherein the first metallic layer is produced in step d) from pure lead, pure indium or pure tin and the connection of the first contact face to the first connection face is free from plastically deformable pure metals Pb, Cd, In and Sn.

10. The method as claimed in claim 1, wherein the semiconductor chip takes the form of a laser bar.

11. The method as claimed in claim 1, further comprising producing a third metallic layer having a nubbed structure on the second connection face or on the second contact face.

12. A diode laser comprising at least one edge-emitting laser bar which comprises one or more emitters, having a first contact face, which takes the form of a p-type contact, and a second contact face , which takes the form of an n-type contact, a heat-conducting body having a first connection face, a cover having a second connection face, where the laser bar is disposed between the heat-conducting body and the cover where the cover is connected mechanically to the heat-conducting body, and the first contact face is areally connected thermally and electrically to the first connection face via an intermetallic layer, and the second contact face is connected electrically to the second connection face, where the intermetallic layer comprises gold (Au) and at least one further metal (ME) from the group lead, cadmium, indium and tin, and the intermetallic layer consists predominantly of one or more mixed phases AuME₃, AuME₂ and/or phases with higher gold fraction.

13. The diode laser as claimed in claim 12, wherein the cover is provided so as to contribute to the diversion of heat from the second contact face and/or the cover is connected thermally and mechanically to the heat-conducting body by means of an electric insulating joining agent.

14. The diode laser as claimed in claim 12, wherein the connection of the first contact face to the first connection face is free from plastically deformable pure metals Pb, Cd, In and Sn.

15. The use of a permanent clamping force for maintaining a securement of a semiconductor component on a heat-conducting body by means of an intermetallic layer, where the intermetallic layer comprises gold (Au) and at least one further metal (ME) from the group lead, cadmium, indium and tin, and the intermetallic layer consists predominantly of one or more mixed phases AuME₃, AuME₂ and/or phases with higher gold fraction.
